(19) United States
(12) Patent Application Publication
(10) Pub. No.: US 2025/0338675 A1
(43) Pub. Date: Oct. 30, 2025

(54) LIGHT-EMITTING STRUCTURE, LIGHT-EMITTING DEVICE, AND LIGHT-EMITTING APPARATUS

(71) Applicant: Hubei San’an Optoelectronics Co., Ltd., Hubei (CN)

(72) Inventors: Chaohsu LAI, Xiamen (CN); Weihua DU, Xiamen (CN); Heqing DENG, Xiamen (CN); Shuiqing LI, Xiamen (CN)

(21) Appl. No.: 19/262,975

(22) Filed: Jul. 8, 2025

Related U.S. Application Data
(63) Continuation-in-part of application No. 17/930,186, filed on Sep. 7, 2022, now Pat. No. 12,369,433.
Application No. 17/930,186 is a continuation-in-part of application No. PCT/CN2020/078410, filed on Mar. 9, 2020.

(51) Int. Cl. H10H 20/812; H10H 20/825

(52) U.S. Cl. CPC H10H 20/812; H10H 20/825

(57) ABSTRACT

A light-emitting structure includes an n-type layer, an active layer, and a p-type layer. The active layer has N quantum well structure periods, each of the N quantum-well structure periods has a well layer and at least one barrier layer. The N quantum-well structure periods include a first light-emitting section and a second light-emitting section. The first light-emitting section is closer to the n-type layer than the second light-emitting section. A light-emitting device that includes the abovementioned light-emitting structure and a light-emitting apparatus that includes the abovementioned light-emitting device are also disclosed.

### CROSS-REFERENCE TO RELATED APPLICATION

This application is a continuation-in-part application of U.S. patent application Ser. No. 17/930,186, which is filed on Sep. 7, 2022, and which is a continuation-in-part application of PCT International Application No. PCT/CN2020/078410 filed on Mar. 9, 2020. The aforesaid applications are incorporated by reference herein in their entirety.

### FIELD

The present disclosure relates to a semiconductor optoelectronic device, and more particularly to a light-emitting structure, a method for producing the light-emitting structure, and a light-emitting device including the light-emitting structure.

### BACKGROUND

A conventional light-emitting structure used in a light-emitting diode generally has a peak wall plug efficiency (Peak WPE) at a current density greater than 5 A/cm². FIG. 11 illustrates the relationship between wall plug efficiency (WPE) and current density, the conventional light-emitting structure is commonly operated at a relatively high current density of greater than 10 A/cm².

However, a mobile device such as a smart phone or a wearable device including a smart watch and a smart band requires a micro light-emitting diode operable at a nanoampere-level current, which is convertible into a current density ranging from 0.1 A/cm² to 1 A/cm². At low current densities of less than 1 A/cm², the photoelectric conversion efficiency of the conventional light-emitting structure will be very unstable, and the photoelectric conversion efficiency may drop sharply as the current changes only slightly. Therefore, the conventional light-emitting structure is inapplicable to electronic devices operated at low current.

Regarding the development of a light-emitting structure for micro light-emitting diodes in electronic devices operated at low current, CN 107833953 discloses a growth method for producing a multi quantum well (MQW) structure of a micro light-emitting diode. The multi quantum well structure includes a blocking layer interposed between a well layer and a barrier layer. The well layer is made of indium gallium nitride (InGaN). The blocking layer and the barrier layer are made of gallium nitride (GaN), and hydrogen gas is introduced as a carrier gas during a deposition process of the barrier layer. However, quality and stress of lattices in the MQW structure of CN 107833953 are unsatisfying, and there is still a need in the art to provide an improved light-emitting structure applicable to the electronic devices operated at low current.

### SUMMARY

Therefore, an object of the disclosure is to provide a light-emitting structure, a light-emitting device including the light-emitting structure, and a light-emitting apparatus including the light-emitting device, which can alleviate or overcome the aforesaid shortcomings of the prior art.

According to a first aspect of the disclosure, a light-emitting structure includes an n-type layer, an active layer, and a p-type layer. The active layer is disposed on the n-type layer and has N quantum-well structure periods. Each of said N quantum-well structure periods has a well layer and at least one barrier layer. The p-type layer is disposed on the active layer and opposite to the n-type layer. The N quantum-well structure periods include N₁ quantum-well structure periods that define a first light-emitting section, and N₂ quantum-well structure periods that define a second light-emitting section. Each of N₁ and N₂ is not less than 1, and N₁+N₂ is not greater than N. The first light-emitting section is closer to the n-type layer than the second light-emitting section. Each of the N₂ quantum-well structure periods that define the second light-emitting section has a first barrier layer, a second barrier layer, a third barrier layer, the well layer, and a fourth barrier layer, where the second barrier layer is disposed between the first barrier layer and the third barrier layer, and the fourth barrier layer is disposed on the well layer opposite to the third barrier layer. In each of the N₂ quantum-well structure periods, a relative content of aluminum of the second barrier layer is greater than a relative content of aluminum of the first barrier layer and a relative content of aluminum of the third barrier layer, and a relative content of aluminum of the fourth barrier layer is greater than the relative content of aluminum of the first barrier layer, the relative content of aluminum of the second barrier layer and the relative content of aluminum of the third barrier layer.

According to a second aspect of the disclosure, a light-emitting device includes the abovementioned light-emitting structure.

According to a third aspect of the disclosure, a light-emitting apparatus includes the abovementioned light-emitting device.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a light-emitting structure of a first embodiment according to the present disclosure;

FIG. 2 is a schematic view illustrating a first light-emitting section of the first embodiment;

FIG. 3 is a schematic view illustrating a third light-emitting section of the first embodiment;

FIG. 4 is a schematic view illustrating a second light-emitting section of the first embodiment;

FIG. 5 is a schematic view illustrating a bandgap structure of an active layer of the first embodiment;

FIG. 6 is a schematic view illustrating a first light-emitting section of a light-emitting structure of a second embodiment according to the present disclosure;

FIG. 7 is a schematic view illustrating a third light-emitting section of the second embodiment;

FIG. 8 is a schematic view illustrating the second light-emitting section of the second embodiment;

FIG. 9 is a light output power (LOP) vs. wavelength (WLD) plot, illustrating a comparison between a light-emitting device of the present disclosure and a conventional light-emitting diode at a current density of 0.5 A/cm²;

FIG. 10 is a photoelectric conversion efficiency vs. current density plot illustrating a comparison between the light-emitting device of the present disclosure and the conventional light-emitting diode; and

FIG. 11 is a photoelectric conversion efficiency vs. current density plot of a light-emitting epitaxial structure of a conventional light-emitting diode.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

The light-emitting structure of the present disclosure is configured as a light-emitting epitaxial structure.

### First Embodiment

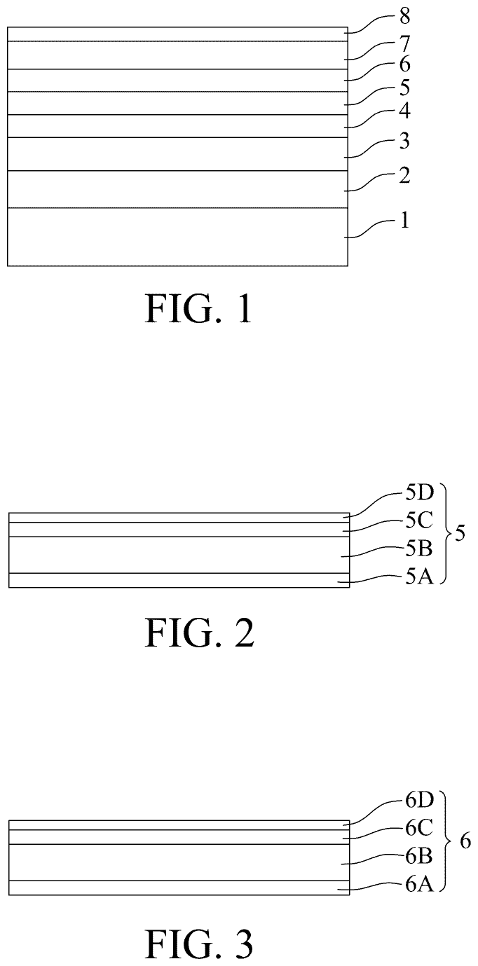

Referring to FIG. 1, a light-emitting structure of the first embodiment according to the present disclosure is formed on a substrate 1. The light-emitting structure of the first embodiment includes an un-doped gallium nitride (u-GaN) layer 2, an n-type layer 3, a stress releasing layer 4, an active layer, and a p-type layer 8 that are disposed on the substrate 1 in such order. In this embodiment, the n-type layer 3 is formed as an n-doped gallium nitride (n-GaN) layer.

The active layer includes N quantum-well structure periods. Each of the N quantum-well structure periods has a well layer and at least one barrier layer. The N quantum-well structure periods include N₁ quantum-well structure periods that defines a first light-emitting section 5, N₂ quantum-well structure periods that defines a second light-emitting section 7, and N₃ quantum-well structure periods that defines a third light-emitting section 6. It should be noted that, in this embodiment, the quantum-well structure periods are referred as the number of the quantum-well structures. In this embodiment, each of N₁, N₂, and N₃ ranges from 1 to 5. The first light-emitting section 5 is closer to the n-type layer 3 than the second light-emitting section 7, and the third light-emitting section 6 is interposed between the first light-emitting section 5 and the second light-emitting section 7. Each of N₁, N₂, and N₃ is greater than or equal to 1 (i.e., each of N₁, N₂ and N₃ is not less than 1), and N₁+N₂ is not greater than N.

Referring to FIG. 2, each of the N₁ quantum-well structure periods of the first light-emitting section 5 sequentially has a first barrier layer 5A, a second barrier layer 5B, a third barrier layer 5C, and the well layer 5D; specifically, the second barrier layer 5B is disposed between the first barrier layer 5A and the third barrier layer 5C. In this embodiment, in each of the N₁ quantum-well structure periods of the first light-emitting section 5, the second barrier layer 5B has a bandgap greater than those of the first barrier layer 5A and the third barrier layer 5C. In each of the N₁ quantum-well structure periods, a relative content of aluminum of the second barrier layer 5B is greater than a relative content of aluminum of the first barrier layer 5A and a relative content of aluminum of the third barrier layer 5C. In each of the N₁ quantum-well structure periods, the second barrier layer 5B has a thickness greater than those of the first barrier layer 5A and the third barrier layer 5C.

Referring to FIG. 3, each of the N₃ quantum-well structure periods of the third light-emitting section 6 sequentially has a first barrier layer 6A, a second in barrier layer 6B, a third barrier layer 6C, and a well layer 6D. In this embodiment, in each of the N₃ quantum-well structure periods of the third light-emitting section 6, the second barrier layer 6B has a bandgap greater than those of the first barrier layer 6A and the third barrier layer 6C. In each of the N₃ quantum-well structure periods, a relative content of aluminum of the second barrier layer 6B is greater than a relative content of aluminum of the first barrier layer 6A and a relative content of aluminum of the third barrier layer 6C.

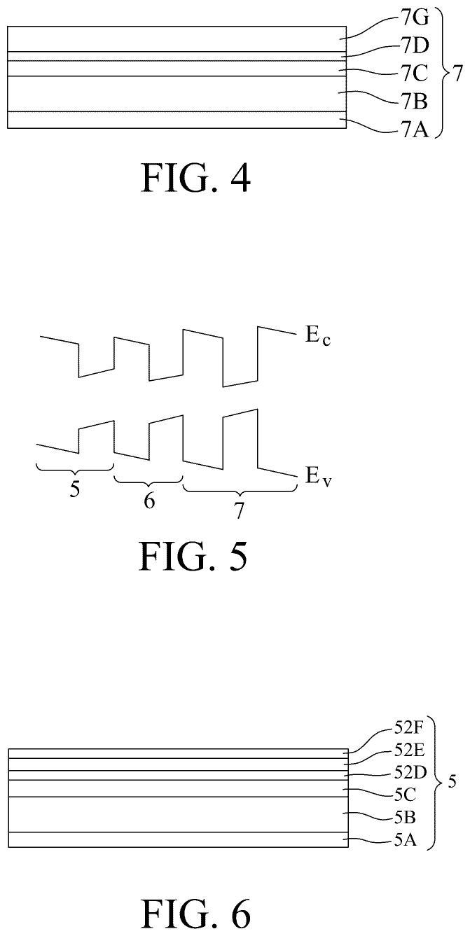

Referring to FIG. 4, each of the N₂ quantum-well structure periods of the second light-emitting section 7 sequentially has a first barrier layer 7A, a second barrier layer 7B, a third barrier layer 7C, the well layer 7D, and a fourth barrier layer 7G; specifically, the second barrier layer 7B is disposed between the first barrier layer 7A and the third barrier layer 7C, and the fourth barrier layer 7G is disposed on the well layer 7D opposite to the third barrier layer 7C. In this embodiment, in each of the N₂ quantum-well structure periods of the second light-emitting section 7, the second barrier layer 7B has a bandgap greater than those of the first barrier layer 7A and the third barrier layer 7C, and the fourth barrier layer 7G has a bandgap greater than that of the second barrier layer 7B. In each of the N₂ quantum-well structure periods, a relative content of aluminum of the second barrier layer 7B is greater than a relative content of aluminum of the first barrier layer 7A and a relative content of aluminum of the third barrier layer 7C, and a relative content of aluminum of the fourth barrier layer 7G is greater than the relative content of aluminum of the first barrier layer 7A, the relative content of aluminum of the second barrier layer 7B and the relative content of aluminum of the third barrier layer 7C.

Referring to FIG. 5, the first, second and third barrier layers 5A, 5B, 5C of the N₁ quantum-well structure periods of the first light-emitting section 5 has an average bandgap less than that of the N₂ quantum-well structure periods of the second light-emitting section 7. The first, second and third barrier layers 7A, 7B, 7C of the N₃ quantum-well structure periods of the third light-emitting section 7 have an average bandgap greater than that of the N₁ quantum-well structure periods of the first light-emitting section 5, and is less than that of the N₂ quantum-well structure periods of the second light-emitting section 7. The well layer 5D of the N₁ quantum-well structure periods of the first light-emitting section 5 has an average bandgap that is not less than the well layer 7D of the N₂ quantum-well structure periods of the second light-emitting section 7. The well layers of the N₃ quantum-well structure periods of the third light-emitting section 6 have an average bandgap greater than that of the N₂ quantum-well structure periods of the second light-emitting section 7, and is less than that of the N₁ quantum-well structure periods of the first light-emitting section 5.

In this embodiment, in each of the N quantum-well structure periods, each of the first 5A, 6A, 7A, second 5B, 6B, 7B, third 5C, 6C, 7C, and fourth 7G barrier layers has a thickness ranging from 10 Å to 1000 Å; and the well layer 5D, 6D, 7D has a thickness ranging from 1 Å to 100 Å. Furthermore, the second barrier layer 5B, 6B, 7B of each of the N quantum-well structure periods has a thickness greater than those of the first barrier layer 5A, 6A, 7A and the third barrier layer 50, 60, 7C.

Each of the N quantum-well structure periods has a ratio of a total thickness of the first 5A, 6A, 7A, second 5B, 6B, 7B, and third 50, 6C, 7C barrier layers to the thickness of the well layer 5D, 6D, 7D ranging from 5:1 to 20:1. In other words, each of the N₁ quantum-well structure periods has a ratio of a total thickness of the first barrier layer 5A, the second barrier layer 5B, and the third barrier layer 5C to a thickness of the well layer 5D ranging from 5:1 to 20:1. Furthermore, each of the N₂ quantum-well structure periods of the second light-emitting section 7 has a ratio of a total thickness of the fourth barrier layer 7G to the thickness of the well layer 7D ranging from 5:1 to 20:1.

In each of the N₂ quantum-well structure periods of the second light-emitting section 7, the thickness of the fourth barrier layer 7G is greater than those of the first barrier layer 7A and the third barrier layer 7C.

In some embodiments, at least one of the first barrier layer, the second barrier layer or the third barrier layer of each of the N₁ quantum-well structure periods and the N₂ quantum-well structure periods is an n-type doped layer. In some embodiments, each of the first barrier layers 5A, 6A, 7A, the second barrier layers 5B, 6B, 7B and the third barrier layers 50, 6C, 7C of each of the N₁ quantum-well structure periods, the N₃ quantum-well structure periods, and the N₂ quantum-well structure periods is an n-type doped layer. The n-type doping layer has an n-type doping concentration ranging from 1×10¹⁷/cm³ to 1×10¹⁹/cm³. Furthermore, the fourth barrier layer 7G of each of N₂ quantum-well structure periods of the second light-emitting section 7 is an unintentionally doped layer. For each of the N₃ quantum-well structure periods, at least one of the first barrier layer 6A, the second barrier layer 6B, or the third barrier layer 6C is an n-type doped layer, which has an n-type doping concentration ranging from 1×10¹⁷/cm³ to 1×10¹⁹/cm³.

The well layer 5D, 6D, 7D of each of the N quantum-well structure periods (i.e., each of the N₁ quantum-well structure periods, the N₂ quantum-well structure periods, and the N₃ quantum-well structure) is made of AlₓIn_{y}Ga_{1-x-y}N. Each of the first 5A, 6A, 7A, second 5B, 6B, 7B and third 50, 6C, 7C barrier layers of each of the N quantum-well structure periods (i.e., each of the N₁ quantum-well structure periods, the N₂ quantum-well structure periods, and the N₃ quantum-well structure) and the fourth barrier layer 7G of each of the N₂ quantum-well structure periods of the second light-emitting section 7 are made of AlₚIn_{q}Ga_{1-p-q}N, where 0≤x<p<1, and 0≤q<y<1.

A method for producing the light-emitting structure shown in the FIGS. 1 to 5 is described below. The method includes the following steps S1 to S5:

In step S1, a substrate 1 is provided. The substrate 1 may be, including but not limited to, a sapphire (Al₂O₃) substrate, an aluminum nitride (AlN)-coated sapphire (Al₂O₃) substrate, a silicon nitride (SiNₓ)-coated sapphire (Al₂O₃) substrate, a gallium oxide (Ga₂O₃) substrate, an AlN-coated Ga₂O₃ substrate, a SiNₓ-coated Ga₂O₃ substrate, a silicon carbide (SiC) substrate, a gallium nitride (GaN) substrate, a zinc oxide (ZnO) substrate, a silicon substrate, or a germanium substrate, etc. In this embodiment, the substrate 1 is an AlN-coated sapphire substrate.

In step S2, a material (e.g. aluminum gallium nitride) is deposited on the substrate 1 to form a nucleation layer (not shown in the figures) by an epitaxial process. The epitaxial process may be metalorganic chemical vapor deposition (MOCVD), molecular beam epitaxy (MBE), chemical vapor deposition (CVD), hydride vapor phase epitaxy (HVPE), plasma-enhanced chemical vapor deposition (PECVD), etc., but is not limited to thus. In this embodiment, the nucleation layer is formed by the MOCVD.

It should be noted that, in this step, the substrate 1 (i.e. AlN-coated sapphire substrate) is placed in the metalorganic chemical vapor deposition chamber. A hydrogenation treatment is performed to remove impurities from a surface of the substrate 1. Then, the chamber is reduced to be from about 500° C. to about 600° C., and aluminum gallium nitride is deposited on the substrate 1 to form the nucleation layer that has a thickness of about 20 nm.

In step S3, the u-GaN layer 2 and the n-type layer 3 are sequentially formed on the nucleation layer.

It should be noted that, a relatively large difference of lattice constants between the substrate 1 and the n-type layer 3 might cause lattice mismatch to occur therebetween. If the lattice mismatch is obvious, a crystal quality of the semiconductor layer (i.e. the n-type layer 3) may be adversely affected. Therefore, the u-GaN layer 2 is used to reduce the lattice mismatch, so as to enhance crystal quality of the n-type layer 3. In addition, in this embodiment, formation of the u-GaN layer 2 involves an epitaxial growth process in a three-dimensional mode and a two-dimensional mode. On the basis of the nucleation layer, the u-GaN layer 2 is formed into an island-like structure in the three-dimensional mode so as to maximize the turning and merging of dislocations between the nucleation layer and the u-GaN layer 2. Then, the epitaxial growth process of the u-GaN layer 2 is turned to the two-dimensional mode to form a flattened surface. The u-GaN layer 2 as grown, has a thickness ranging from 1 μm to 3 μm. Then, n-GaN is deposited on the u-GaN layer 2 to form the n-type layer 3. In this embodiment, the n-type layer 3 is an N—GaN layer and has a thickness ranging from 1 μm to 3 μm, and a doping concentration ranging from 1×10¹⁹/cm³ to 2.5×10¹⁹/cm³.

In step S4, the stress release layer 4 is deposited on the n-type layer 3. In this embodiment, the temperature is reduced to a range of 750° C. to 950° C. The stress release layer 4 is formed by alternately depositing indium gallium nitride and gallium nitride to form a super lattice structure layer or form another combination structure. Consequently, a mismatch between the stress release layer 4 and the subsequently formed active layer that has a relatively high indium content and between the stress release layer 4 and the N—GaN layer (the n-type layer 3) is reduce, the stress is released and the lattice quality is enhanced.

In step S5, the first light-emitting section 5 of the active layer is formed on the stress releasing layer 4.

It should be noted that, in this embodiment, the temperature is raised to a barrier-layer forming temperature ranging from 800° C. to 900° C. The first barrier layer 5A may be made of gallium nitride-based materials. In this embodiment, the first barrier layer 5A is made of Silicon (Si)-doped gallium nitride and deposited on the stress releasing layer 4 in such temperature with a growth rate of about 0.9 Å/s. The first barrier layer 5A as formed has a thickness ranging from about 5 Å to about 50 Å, and a silicon doping concentration ranging from about 1×10¹⁷/cm³ to about 1×10¹⁹/cm³.

Thereafter, the second barrier layer 5B is deposited on the first barrier layer 5A. The second barrier layer 5B may be made of aluminum gallium nitride-based materials. In this embodiment, the second barrier layer 5B is made of Si-doped aluminum gallium nitride and formed at the previous temperature raised by 10° C. to 50° C., at a growth rate of about 1.5 Å/s. The second barrier layer 5B as formed has the thickness ranging from about 30 Å to about 100 Å, a relative content of aluminum ranging from about 1% to about 10% (preferably, 1.5%), and a silicon doping concentration ranging from about 1×10¹⁷/cm³ to about 1×10¹⁹/cm³. During formation of the second barrier layers 5B, a trimethylaluminum (TMAL) gas of 2 sccm is introduced.

After the second barrier layer 5B is formed, introduction of TMAL gas is stopped. Then, the third barrier layer 5C is deposited on the second barrier layer 5B. The third barrier layer 5C may be made of gallium nitride-based materials. In this embodiment, the third barrier layer 5C is made of silicon-doped gallium nitride and formed at the previous temperature reduced by 10° C. to 50° C. and at a growth rate of about 0.9 Å/s. The third barrier layer 5C as formed has the thickness ranging from about 5 Å to about 50 Å, and a silicon doping concentration ranging from about 1×10¹⁷/cm³ to about 1×10¹⁹/cm³. During formation of the third barrier layer 5C, a SiH₄ gas is introduced.

Then, the well layer 5D is deposited on the third barrier layer 5C, introduction of the SiH₄ gas is stopped. In this embodiment, the well layer 5D made of indium gallium nitride is formed at the temperature reduced to a range of 700° C. to 800° C. at a growth rate of about 0.3 Å/s. The well layer 5D as formed has the thickness ranging from 5 Å to 50 Å (in certain embodiments, 20 Å) and an average indium content that is about 18%. During the formation of the well layer 5D, a trimethylindium (TMIN) gas of 800 sccm is introduced.

In this step S5, formation of each the quantum well structure periods of the first light-emitting section 5, i.e., formation of the first, second, and third barrier layers 5A, 5B, 5C, and the well layer 5D, may be repetitively performed 1 to 5 times, thereby obtaining the first light-emitting section 5 that has the N₁ quantum-well structure periods, where N₁ ranges from 1 to 5. In addition, the N₁ quantum-well structure periods may each have the same composition.

In this embodiment, the N₁ is two. The bandgap of the second barrier layer 5B is not less than or equal to those of the first barrier layer 5A and the third barrier layer 5C, thereby suppressing a carrier overflow effectively to adjust a bandgap configuration of the active layer. Moreover, in order to enhance the manufacturing efficiency and improve the lattice quality of the active layer, the temperature and the growth rate are adjustably adapted for the formation of different barrier layers, i.e., the temperature and the growth rate are different in each process for forming the first, second, and third barrier layers 5A, 5B, 5C.

In step S6, the third light-emitting section 6 is formed on the first light-emitting section 5 opposite to the stress releasing layer 4.

It should be noted that, in this embodiment, the temperature is raised to a range of 800° C. to 900° C. Then, the first barrier layer 6A made of gallium nitride is deposited on the first light-emitting section 5 at a growth rate of about 0.6 Å/s. The first barrier layer 6A is an unintentionally doped layer and has a thickness ranging from about 5 Å to about 50 Å.

Then, the second barrier layer 6B is deposited on the first barrier layer 6A. The second barrier layer 6B may be made of aluminum gallium nitride-based materials. In this embodiment, the second barrier layer 6B is made of Si-doped aluminum gallium nitride and formed at the previous temperature increased by 10° C. to 50° C. and at a growth rate of about 0.9 Å/s. The second barrier layer 6B as formed has the thickness ranging from about 30 Å to about 100 Å, a relative content of aluminum ranging from about 1% to about 10% (preferably, 2%), and a silicon doping concentration ranging from about 1×10¹⁷/cm³ to about 1×10¹⁹/cm³. During formation of the second barrier layer 6B, the TMAL gas of 2.5 sccm is introduced.

Then, the third barrier layer 6C is deposited on the second barrier layer 6B, and introduction of the TMAL gas is stopped. The third barrier layer 6C may be made of gallium nitride-based materials. In this embodiment, the third barrier layer 6C is made of Si-doped gallium nitride and formed at the previous temperature reduced by 10° C. to 50° C. and at a growth rate of about 0.6 Å/s. The third barrier layer 6C as formed has the thickness ranging from about 5 Å to about 50 Å and a silicon doping concentration ranging from about 1×10¹⁷/cm³ to about 1×10¹⁹/cm³. During formation of the third barrier layer 6C, a SiH₄ gas is introduced.

After the third barrier layer 6C is formed, introduction of the SiH₄ gas is stopped, and the temperature is reduced to a range of 700° C. to 800° C. The well layer 6D made of indium gallium nitride is deposited on the third barrier layer 6C at a growth rate of about 0.2 Å/s. The well layer 6D as formed has the thickness ranging from about 5 Å to about 50 Å (in certain embodiments, 20 Å) and an average indium content that is about 19%. During formation of the well layer 6D, the TMIN gas of 900 sccm is introduced.

In this step, formation of each the quantum well structure periods of the second light-emitting section 6, i.e., formation of the first, second, and third barrier layers 6A, 6B, 6C, and the well layer 6D, may be repetitively performed 1 to 5 times, thereby obtaining the third light-emitting section 6 that has the N₃ quantum-well structure periods, where N₃ ranges from 1 to 5. In addition, the N₃ quantum-well structure periods may each have the same composition.

In this embodiment, the N₃ is two. The average bandgap of the first, second and third barrier layers 6A, 6B, 6C of the N₃ quantum-well structure periods of the third light-emitting section is greater than that of the N₁ quantum-well structure periods of the first light-emitting section 5; and the average bandgap of the well layers of the N₃ quantum-well structure periods of the third light-emitting section 6 is less than that of the N₁ quantum-well structure periods of the first light-emitting section 5, so that the carrier overflow in the third light-emitting section 6 that is relatively close to the p-type layer 8 than the first light-emitting section 5 can be suppressed effectively, thus a carrier transport and a recombination effect in a low injection current can be improved. In addition, the first, second and third barrier layers 6A, 6B, 6C of the third light-emitting section 6 are grown at the growth rate that is less than or equal to that of the first, second and third barrier layers 5A, 5B, 5C of the first light-emitting section 5, and the well layer 6D of the third light-emitting section 6 is grown at the growth rate that is less than or equal to that of the well layer 5D of the first light-emitting section 5, so that the third light-emitting section 6 may have superior lattice quality.

In step 7, the second light-emitting section 7 is formed on the third light-emitting section 6 opposite to the first light-emitting section 5.

In this embodiment, the temperature is raised to a range of 800° C. to 900° C. Then, the first barrier layer 7A made of gallium nitride is deposited on the third light-emitting section 6 at a growth rate of about 0.3 Å/s. In this embodiment, the first barrier layer 7A is an unintentionally doped layer, and has the thickness ranging from about 5 Å to about 50 Å.

Then, the second barrier layer 7B is deposited on the first barrier layer 7A. The second barrier layer 7B may be made of aluminum gallium nitride-based materials. In this embodiment, the second barrier layer 7B is made of Si-doped aluminum gallium nitride and formed at the temperature raised by 10° C. to 50° C. at a growth rate of about 0.5 Å/s. The second barrier layer 7B as formed has a thickness ranging from about 30 Å to about 100 Å, a relative content of aluminum ranging from about 1% to about 10% (preferably, 2.5%), and a silicon doping concentration ranging from about 1×10¹⁷/cm³ to about 1×10¹⁹/cm³. During formation of the second barrier layer 7B, the TMAL gas of 3 sccm is introduced.

Then, the third barrier layer 7C is deposited on the second barrier layer 7B, and introduction of the TMAL gas is stopped. The third barrier layer 7C may be made of gallium nitride-based materials. In this embodiment, the third barrier layer 7C is made of Si-doped gallium nitride and formed at the previous temperature reduced by 10° C. to 50° C. at a growth rate of about 0.3 Å/s. The third barrier layer 7C as formed has the thickness ranging from about 5 Å to about 50 Å.

After the third barrier layer 7C is formed, the temperature is reduced to a range of 700° C. to 800° C. The well layer 7D made of indium gallium nitride is deposited on the third barrier layer 7C at a growth rate of about 0.1 Å/s. The well layer 7D as formed has a thickness ranging from 5 Å to 50 Å (in certain embodiments, 20 Å), and an average indium content that is about 20%. During formation of the well layer 7D, the TMIN gas of 1000 sccm is introduced. An average of the relative contents of aluminum of the first barrier layers 5A, the second barrier layers 5B and the third barrier layers 5C of the N₁ quantum-well structure periods is less than an average of the relative contents of aluminum of the first barrier layers 7A, the second barrier layers 7B, the third barrier layers 7C and the fourth barrier layers 7G of the N₂ quantum-well structure periods, and an average of indium contents of the well layers 5D of the N₁ quantum-well structure periods is less than an average of indium contents of the well layers 7D of the N₂ quantum-well structure periods. In some embodiments, an average of relative contents of aluminum of the barrier layers of the N₃ quantum-well structure periods is between the average of the relative contents of aluminum of the first barrier layers 5A, the second barrier layers 5B and the third barrier layers 5C of the N₁ quantum-well structure periods and the average of the relative contents of aluminum of the first barrier layers 7A, the second barrier layers 7B, the third barrier layers 7C and the fourth barrier layers 7G of the N₂ quantum-well structure periods, and an average of indium contents of the well layers 6D of the N₃ quantum-well structure periods is between the average of the indium contents of the well layers 5D of the N₁ quantum-well structure periods and the average of the indium contents of the well layers 7D of the N₂ quantum-well structure periods.

After the well layer 7D is formed, the temperature is raised to the range of 800° C. to 900° C. Then, the fourth barrier layer 7G made of gallium nitride and aluminum gallium nitride is deposited on the well layer 7D at a growth rate of 0.5 Å/s. The fourth barrier layer 7G has a thickness ranging from about 50 Å to about 100 Å and a relative content of aluminum ranging from about 5% to about 50% (preferably, 15%).

In this step, formation of each of the quantum well structure periods of the second light-emitting section 7, i.e., formation of the first, second, third barrier layer 7A, 7B, 7C, the well layer 7D, and the fourth barrier layer 7G, may be repetitively performed 1 to 5 times, thereby obtaining the second light-emitting section 7 that has the N₂ quantum-well structure periods, where N₂ ranges from 1 to 5. In addition, the N₂ quantum-well structure periods may each have the same composition. In this embodiment, the N₂ is 1.

Referring to FIG. 5, the average bandgap of the first, second, third and fourth barrier layers 7A, 7B, 7C, 7G of the second light-emitting section 7 is greater than the first, second and third barrier layers 6A, 6B, 6C of the third light-emitting section 6 and the first light-emitting section 5; and the average bandgap of the well layers 7D of the second light-emitting section 7 is less than those of the third light-emitting section 6 and the first light-emitting section 5. Furthermore, the bandgap of the fourth barrier layer 7G is greater than or equal to those of the first 7A, second 7B, and third 7C barrier layers, so that the carrier overflow can be effectively suppressed, and the carrier transport and the recombination effect in the low injection current can be improved.

In this embodiment, the barrier layers 5A, 5B, 5C of the first light-emitting section 5 are grown at an average growth rate greater than that of the barrier layers 7A, 7B, 7C, 7G of the second light-emitting section 7. In each of the N quantum-well structure periods, either of the first barrier layer and the third barrier layer are grown at an average growth rate not greater than that of the second barrier layer. The well layer 7D of the second light-emitting section 7 be grown at an average growth rate of not greater than those of the first light-emitting section 5 and third light-emitting section 6. Therefore, the second light-emitting section 7 that is relatively close to the p-type layer 8 than the first light-emitting section 5 and the third light-emitting section 6 may be formed at a relatively low growth rate, so as to obtain a superior lattice quality, thus the carrier overflow can be suppressed effectively, and the carrier transport, the recombination effect, and the light-emitting efficiency in the low injection current can be improved.

Thus, the active layer of the embodiment may be obtained. In such configuration of the active layer, recombination efficiency and injection efficiency of the carriers may be enhanced, the carrier overflow may be suppressed effectively, and wavelength overlapping of the electrons and holes may be increased, thus the carrier transport and the recombination effect in the low injection current can be improved. It should be noted that, the active layer is configured to have a plurality of the light-emitting sections (i.e. the first, second, and third light-emitting sections 5, 6, 7) that are made at different growth rates and have different thicknesses respectively, thereby reducing the lattice mismatch between the active layer and the bottom layer, or between the well layers and the barrier layers of the active layer, reducing the stress to improve the crystal quality of the active layer, so that a peak value efficiency reach at low current density to enhance the light-emitting efficiency at low current.

In step 8, the p-type layer 8 is formed on the active layer (i.e. the second light-emitting section 7).

In certain embodiments, the p-type layer 8 may be configured to have a low-temperature p-type layer, a high-temperature p-doped aluminum gallium nitride (p-AlGaN) layer, and a high-temperature p-doped gallium nitride (p-GaN) layer (none of which are shown in the figures). The low-temperature p-type layer is used to ensure the active layer not to be damaged by the high temperature, and to provide improved hole injection efficiency. Furthermore, after the low-temperature p-type layer is formed, the temperature is raised to grow the high-temperature p-AlGaN layer and the high-temperature p-GaN layer to planarize a surface of the low-temperature p-type layer.

Thus, the light-emitting structure of the first embodiment of the present disclosure may be obtained. In some embodiments, the light-emitting structure of the first embodiment may be used to produce a micro light-emitting diode chip that has a horizontal area of 19×31 μm², but is not limited to thus.

### Second Embodiment

The light-emitting structure of the second embodiment according to the present disclosure is generally similar to that of the first embodiment, except for the configuration of the active layer.

Referring to FIG. 6, each of the N₁ quantum-well structure periods of the first light-emitting section 5 sequentially has the first barrier layer 5A, the second barrier layer 5B, the third barrier layer 5C, a first well layer 52D, a second well layer 52E, and a third well layer 52F.

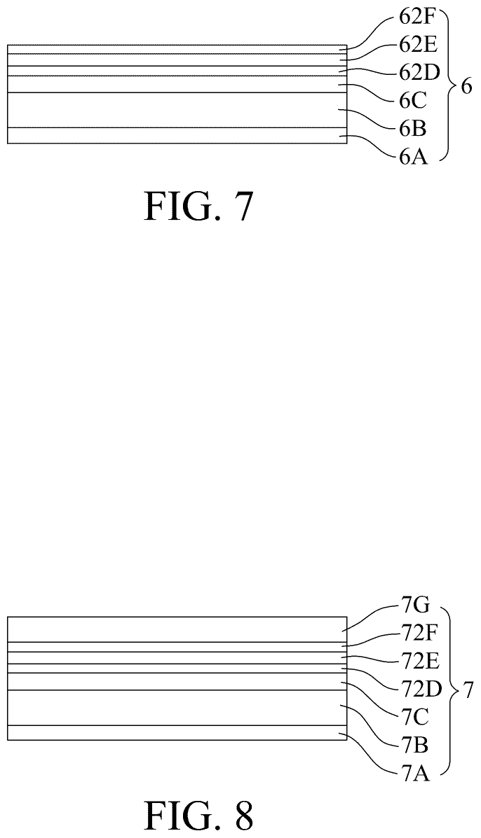

Referring to FIG. 7, each of the N₃ quantum-well structure periods of the third light-emitting section 6 sequentially has the first barrier layer 6A, the second barrier layer 6B, the third barrier layer 6C, a first well layer 62D, a second well layer 62E, and a third well layer 62F.

Referring to FIG. 8, each of the N₂ quantum-well structure periods of the second light-emitting section 7 sequentially has the first barrier layer 7A, the second barrier layer 7B, the third barrier layer 7C, a first well layer 72D, a second well layer 72E, a third well layer 72F, and the fourth barrier layer 72G.

The method for producing the light-emitting structure of the second embodiment is generally similar to that of the first embodiment, except for the following differences.

Referring to FIG. 6, in the step S5 that is for forming the first light-emitting section 5, after the third barrier layer 5C is formed, the well layer-forming temperature is reduced to a range of 700° C. to 800° C. In the process of reducing the temperature, the first well layer 52D begins to be formed at a growth rate of about 0.6 Å/s, in this embodiment, the first well layer 52D is an indium gallium nitride layer, and has a thickness ranging from about 3 Å to about 8 Å. During the process for forming the first well layer 52D, the TMIN gas of 1000 sccm is introduced.

After the first well layer 52D is formed, the second well layer 52E is formed on the first well layer 52D at a growth rate of about 0.3 Å/s, in this embodiment, the second well layer 52E is an indium gallium nitride layer and has a thickness ranging from about 5 Å to about 15 Å.

After the second well layer 52E is formed, the barrier layer-forming temperature is raised to a range of 700° C. to 800° C. In the process of raising the temperature, the third well layer 52F begins to be formed at a growth rate of about 0.6 Å/s, in this embodiment, the third well layer 52F is an indium gallium nitride layer, and has a thickness ranging from about 3 Å to about 8 Å and the average indium content that is about 20%.

Referring to FIG. 7, in the step S6 that is for forming the third light-emitting section 6, after the third barrier layer 6C is formed, the well-layer forming temperature is reduced to a range of 700° C. to 800° C. In the process of reducing the temperature, the first well layer 62D begins to be formed at a growth rate of about 0.4 Å/s, in this embodiment, the first well layer 62D is an indium gallium nitride layer, and has a thickness ranging from about 3 Å to about 8 Å. During the process for forming the first well layer 62D, the TMIN gas of 1000 sccm is introduced.

After the first well layer 62D is formed, the second barrier layer 62E is formed on the first well layer 62D at a growth rate of about 0.2 Å/s, in this embodiment, the second barrier layer 62E is an indium gallium nitride layer, and has a thickness ranging from about 5 Å to about 15 Å.

After the second barrier layer 62E is formed, the barrier layer-forming temperature is raised to a range of 700° C. to 800° C. (i.e., the temperature of the barrier layer). In the process of raising the temperature, the third well layer 62F is begun to be formed at a growth rate of about 0.4 Å/s, in this embodiment, the third well layer 62F is an indium gallium nitride layer, and has the thickness ranging from about 3 Å to about 8 Å and the average indium content that is about 20%.

Referring to FIG. 8, in the step S7 that is for forming the second light-emitting section 7, after the third barrier layer 7C is formed, the well layer-forming temperature is reduced to a range of 700° C. to 800° C. In the process of reducing the temperature, the first well layer 72D begins to be formed at a growth rate of about 0.2 Å/s, in this embodiment, the first well layer 72D is an indium gallium nitride layer, and has a thickness ranging from about 3 Å to about 8 Å. During the process for forming the first well layer 72D, the TMIN gas of 1000 sccm is introduced.

After the first well layer 72D is formed, the second well layer 72E is formed on the first well layer 72D at a growth rate of about 0.1 Å/s, in this embodiment, the second well layer 72E is an indium gallium nitride layer, and has a thickness ranging from about 5 Å to about 15 Å.

After the second well layer 72E is formed, the barrier layer-forming temperature is raised to a range of 700° C. to 800° C. In the process of raising the temperature, the third well layer 72F begins to be formed at a growth rate of about 0.1 Å/s, in this embodiment, the third well layer 72F is an indium gallium nitride layer, and has a thickness ranging from about 3 Å to about 8 Å and the average indium content that is about 20%. After the third well layer 72F is formed, the fourth barrier layer 7G is formed on the third well layer 72F.

The light-emitting structure of the second embodiment is formed to have multiple well layers, so that the lattice mismatch stress between the well layers having high indium content and the barrier layers can be further reduced. Moreover, in order to improve the lattice mismatch stress between the well layers and the barrier layers in each of the N of quantum-well structure periods, the lattice quality of the active layer, and the performance of the light-emitting device that has the light-emitting structure of the second embodiment at low current, the temperature and the growth rate may be adjusted according to the different well layers, thus the temperature and the growth rate are different in each processes for forming the well layers.

### Third Embodiment

The light-emitting structure of the third embodiment according to the present disclosure is generally similar to that of the first embodiment, except for the following differences.

The active layer does not include the third light-emitting section 6, i.e., the active layer only includes the first light-emitting section 5 and the second light-emitting section 7. In this case, the sum of the N₁ and the N₂ is equal to N (i.e., N₁+N₂=N).

### Fourth Embodiment

The light-emitting structure of the fourth embodiment according to the present disclosure is generally similar to that of the first embodiment, except for the following differences.

In the second light-emitting section 7, the fourth barrier layer 7G may be formed as a single layer that is made of a material that is a combination of gallium nitride, aluminum gallium nitride, and aluminum nitride. Furthermore, the fourth barrier layer 7G may also be formed as a laminated structure that has a gallium nitride layer, an aluminum gallium nitride layer, and an aluminum nitride layer, for instance, the laminated structure may be formed as a gallium nitride layer/aluminum gallium nitride layer/aluminum nitride layer structure that is repeated N times, or a gallium nitride layer/aluminum gallium nitride layer structure that is repeated N times, where 1≤N≤20, and the aluminum content ranges from 5% to 20%. In such configuration, the carrier overflow may be further suppressed, and the wavelength overlapping between electrons and holes may be increased, thus the recombination effect at low current can be improved, and the brightness at low current can be enhanced.

### Fifth Embodiment

The present disclosure also provides the light emitting device that has the substrate 1 AND the aforesaid light-emitting structure formed on the substrate 1. In this embodiment, the light-emitting device has a horizontal area ranging from 1×1 μm² to 300×300 μm².

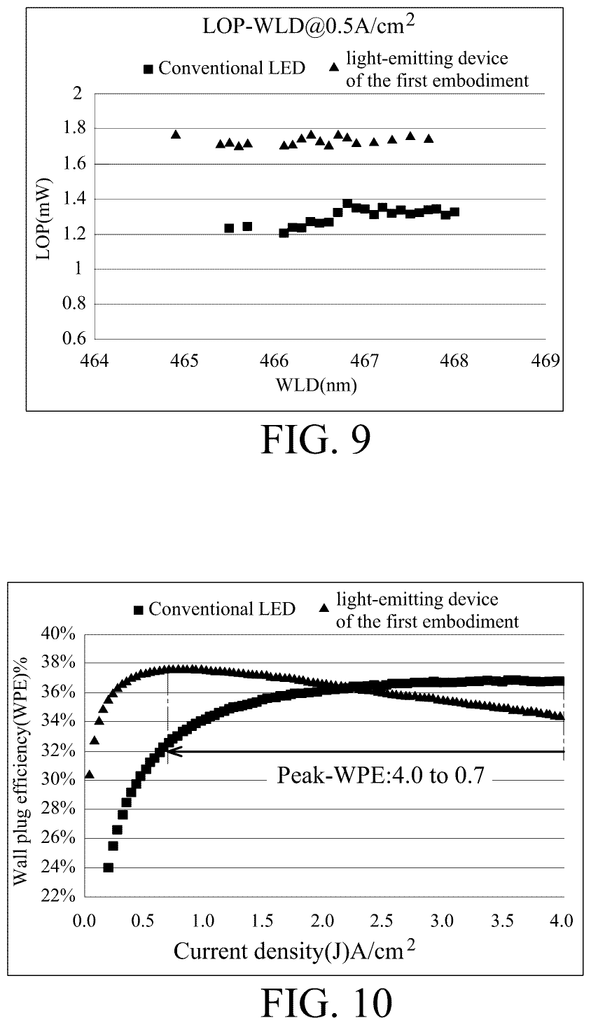

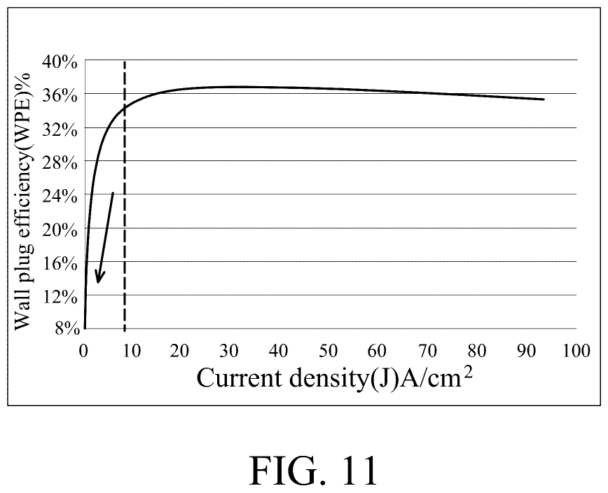

FIGS. 9 and 10 show a comparison between the light-emitting device of the first embodiment and the conventional light-emitting diode. As shown in the FIG. 9, the vertical axis represents a light output power (LOP); and the horizontal axis represents a wavelength (WLD). As a results, the LOP of the light-emitting device of the present disclosure is greater than that of the conventional light-emitting diode by about 30% at a current density of 0.5 Å/cm².

As shown in the FIG. 10, the horizontal axis represents the current density (J); and the vertical axis represents a wall plug efficiency (WPE). As a result, the peak value of the wall plug efficiency (peak-WPE) is reduced from 4 Å/cm² to 0.7 Å/cm².

In other embodiments, one or more the aforesaid light-emitting devices are applicable to make a light-emitting apparatus. An embodiment of the disclosure includes a light-emitting apparatus that includes the abovementioned light-emitting device.

In summary, the light-emitting structure, the light-emitting device, and the production method of the light-emitting structure of the present disclosure have the following advantages:
1. By virtue of the active layer that has a plurality of the light-emitting sections, the carrier overflow in the light-emitting sections can be suppressed effectively, the wavelength overlapping of the electrons and holes can be increased, and the stress in the light-emitting sections can be released effectively, thus the carrier transport and the recombination effect at low injection current can be improved, and a radiative recombination efficiency of the carrier and the photoelectric conversion efficiency can be enhanced.
2. Since each of the light-emitting sections has the relatively thin well layer and the relatively thick barrier layers, and further has a greater ratio of the thickness of the well layer to the barrier layers, growth defect density in the multi quantum well can be reduced, growth quality of the multi quantum well can be noticeably improved, and non-radiative recombination efficiency can be reduced. Therefore, the peak value of the wall plug efficiency would noticeably increase.
3. By virtue of the light-emitting sections that are grown by the different growth rates, the lattice mismatch stress between the well layer and the barrier layers of the active layer can be further improved, and the lattice quality of the active layer can be improved.

It should be noted that, for a micro light-emitting device, a main active layer is referred to as an active layer that is closer to the p-type layer. Therefore, by growing the first light-emitting section 5 that is closer to the n-type layer 4 at a relatively high growth rate; and growing the second light-emitting section 7 that is closer to the p-type layer at a relatively low growth rate, the lattice mismatch stress between a part of the active layer that has the high indium content and the gallium nitride layer can be further reduced. Thus, the lattice quality of the active layer of the micro light-emitting device can be effectively improved, a relatively short growth time can be obtained to enhance the production efficiency.
4. In each the quantum well structure periods, by adjusting the temperature and the growth rate to form the different well layers and different barrier layers, the lattice mismatch stress between the barrier layers and the well layer in each quantum well structure can be improved, thus the lattice quality of the multi quantum well can be improved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting structure, comprising:
an n-type layer;
an active layer disposed on said n-type layer and having N quantum-well structure periods, each of said N quantum-well structure periods having a well layer and at least one barrier layer; and
a p-type layer disposed on said active layer and opposite to said n-type layer,
wherein said N quantum-well structure periods include N₁ quantum-well structure periods that define a first light-emitting section, and N₂ quantum-well structure periods that define a second light-emitting section, each of N₁ and N₂ being not less than 1, N₁+N₂ being not greater than N, said first light-emitting section being closer to said n-type layer than said second light-emitting section;
wherein each of said N₂ quantum-well structure periods that define said second light-emitting section has a first barrier layer, a second barrier layer, a third barrier layer, said well layer, and a fourth barrier layer, where said second barrier layer is disposed between said first barrier layer and said third barrier layer, and said fourth barrier layer is disposed on said well layer opposite to said third barrier layer; and
wherein, in each of said N₂ quantum-well structure periods, a relative content of aluminum of said second barrier layer is greater than a relative content of aluminum of said first barrier layer and a relative content of aluminum of said third barrier layer, and a relative content of aluminum of said fourth barrier layer is greater than the relative content of aluminum of said first barrier layer, the relative content of aluminum of said second barrier layer and the relative content of aluminum of said third barrier layer.

2. The light-emitting structure as claimed in claim 1, wherein each of said N₁ quantum-well structure periods that define said first light-emitting section has a first barrier layer, a second barrier layer, a third barrier layer, and said well layer, where said second barrier layer is disposed between said first barrier layer and said third barrier layer, and wherein in each of said N₁ quantum-well structure periods, a relative content of aluminum of said second barrier layer is greater than a relative content of aluminum of said first barrier layer and a relative content of aluminum of said third barrier layer.

3. The light-emitting structure as claimed in claim 2, wherein each of said N₁ quantum-well structure periods has a ratio of a total thickness of said first barrier layer, said second barrier layer, and said third barrier layer to a thickness of said well layer ranging from 5:1 to 20:1.

4. The light-emitting structure as claimed in claim 1, wherein each of said N₂ quantum-well structure periods has a ratio of a thickness of said fourth barrier layer to a thickness of said well layer ranging from 5:1 to 20:1.

5. The light-emitting structure as claimed in claim 2, wherein in each of said N₁ quantum-well structure periods, said second barrier layer has a thickness greater than those of said first barrier layer and said third barrier layer.

6. The light-emitting structure as claimed in claim 1, wherein in each of said N₂ quantum-well structure periods, said fourth barrier layer has a thickness greater than those of said first barrier layer and said third barrier layer.

7. The light-emitting structure as claimed in claim 2, wherein at least one of said first barrier layer, said second barrier layer or said third barrier layer of each of said N₁ quantum-well structure periods and said N₂ quantum-well structure periods is an n-type doped layer, and
wherein said fourth barrier layer of each of said N₂ quantum-well structure periods is an unintentionally doped layer.

8. The light-emitting structure as claimed in claim 7, wherein said n-type doping layer has an n-type doping concentration ranging from 1×10¹⁷/cm³ to 1×10¹⁹/cm³.

9. The light-emitting structure as claimed in claim 1, wherein N₁ and N₂ each range from 1 to 5.

10. The light-emitting structure as claimed in claim 2, wherein said well layer of each of said N₁ quantum-well structure periods and said N₂ quantum-well structure periods is made of AlₓIn_{y}Ga_{1-x-y}N, and
wherein said first barrier layer, said second barrier layer, and said third barrier layer of each of said N₁ quantum-well structure periods and said first barrier layer, said second barrier layer, said third barrier layer, and said fourth barrier layer of each of said N₂ quantum-well structure periods are made of AlₚIn_{q}Ga_{1-p-q}N, where 0≤x<p<1, and 0≤q<y<1.

11. The light-emitting structure as claimed in claim 2, wherein an average of said relative contents of aluminum of said first barrier layers, said second barrier layers and said third barrier layers of said N₁ quantum-well structure periods is less than an average of said relative contents of aluminum of said first barrier layers, said second barrier layers, said third barrier layers and said fourth barrier layers of said N₂ quantum-well structure periods, and an average of indium contents of said well layers of said N₁ quantum-well structure periods is less than an average of indium contents of said well layers of said N₂ quantum-well structure periods.

12. The light-emitting structure as claimed in claim 11, wherein said N quantum-well structure periods further includes N₃ quantum-well structure periods that in define a third light-emitting section interposed between said first light-emitting section and said second light-emitting section, an average of relative contents of aluminum of said barrier layers of said N₃ quantum-well structure periods being between said average of said relative contents of aluminum of said first barrier layers, said second barrier layers and said third barrier layers of said N₁ quantum-well structure periods and said average of said relative contents of aluminum of said first barrier layers, said second barrier layers, said third barrier layers and said fourth barrier layers of said N₂ quantum-well structure periods, an average of indium contents of said well layers of said N₃ quantum-well structure periods being between said average of said indium contents of said well layers of said N₁ quantum-well structure periods and said average of said indium contents of said well layers of said N₂ quantum-well structure periods.

13. The light-emitting structure as claimed in claim 12, wherein each of said N₃ quantum-well structure periods has a first barrier layer, a second barrier layer, a third barrier layer, and said well layer, and, in each of said N₃ quantum-well structure periods, a relative content of aluminum of said second barrier layer is greater than a relative content of aluminum of said first barrier layer and a relative content of aluminum of said third barrier layer.

14. The light-emitting structure as claimed in claim 13, wherein in each of said N₃ quantum-well structure periods, said second barrier layer has a thickness greater than those of said first barrier layer and said third barrier layer.

15. The light-emitting structure as claimed in claim 14, wherein each of said N₃ quantum-well structure periods has a ratio of a total thickness of said first barrier layer, said second barrier layer, and said third barrier layer to a thickness of said well layer ranging from 5:1 to 20:1.

16. The light-emitting structure as claimed in claim 13, wherein for each of said N₃ quantum-well structure periods, at least one of said first barrier layer, said second barrier layer, or said third barrier layer is an n-type doped layer, which has an n-type doping concentration ranging from 1×10¹⁷/cm³ to 1×10¹⁹/cm³.

17. The light-emitting structure as claimed in claim 12, N₃ ranges from 1 to 5.

18. A light-emitting device comprising said light-emitting structure as claimed in claim 1.

19. The light-emitting device as claimed in claim 18, wherein said light-emitting device has a horizontal area ranging from 1×1 μm² to 300×300 μm².

20. A light-emitting apparatus comprising said light-emitting device as claimed in claim 18.
